(19) United States
(12) Patent Application Publication
(10) Pub. No.: US 2024/0291238 A1
(43) Pub. Date: Aug. 29, 2024

(54) VERTICAL CAVITY SURFACE EMITTING LASER WITH INTEGRATED PHOTODIODE

(71) Applicant: ZEBRA TECHNOLOGIES CORPORATION, Lincoinshire, IL (US)

(72) Inventors: Chinh Tan, East Setauket, NY (US); David Tsi Shi, Setauket, NY (US); Matthew D. Blasczak, Shirley, NY (US)

(21) Appl. No.: 18/115,708

(22) Filed: Feb. 28, 2023

(51) Int. Cl. H01S 5/183; H01S 5/00; H01S 5/026

(52) U.S. Cl. CPC H01S 5/18327; H01S 5/0014; H01S 5/0262

(57) ABSTRACT

An improved imaging device for use with indicia decoding operations is provided with a vertical cavity surface emitting laser (VCSEL) including: a semiconductor substrate, an upper distributed Bragg reflector (DBR), a lower DBR coupled to the substrate, and at least one photodiode integrated into the substrate which is positioned to receive leakage light from the lower DBR, wherein the VCSEL is configured to emit a beam of light away from the substrate.

### BACKGROUND

When operating a vertical cavity surface emitting laser (VCSEL), safety and regulatory considerations necessitate the need for continual monitoring of optical power output of the VCSEL. A photodiode is used for this purpose which occupies additional space and prevents further miniaturization of indicia scanning equipment which include a VCSEL, so it is desirable to reduce the physical dimensions of the components within an indicia scanning device for the measurement of optical power output.

### SUMMARY

The present disclosure is generally related to an improved imaging device for use with indicia decoding operations that includes a vertical cavity surface emitting laser (VCSEL) with an integrated photodiode for monitoring the VCSEL's optical power output. The device includes several features to allow for reliable measurement and regulation of the optical power output of the VCSEL without the need for beam splitting or additional space requirements beyond that of the VCSEL itself.

One example embodiment of the present disclosure is a device, comprising: an image sensor and an aiming assembly, where the aiming assembly includes: a semiconductor substrate, a VCSEL configured to emit light away from the substrate with an upper distributed Bragg reflector (DBR) and a lower DBR which is coupled directly to the substrate, and a photodiode integrated into the substrate which is positioned to receive leakage light from the lower DBR.

One example embodiment of the present disclosure is a method, comprising: detecting an amount of optical power of a leakage light emitted towards a semiconductor substrate by a distributed Bragg reflector (DBR) coupled directly to the substrate in a VCSEL configured to emit light away from the substrate, calculating an output level of the VCSEL based upon the amount of optical power of the leakage light, and adjusting the output level of the VCSEL responsive to the output level being greater or lesser than a target output level.

### BRIEF DESCRIPTION OF THE DRAWINGS

The accompanying figures depict various elements of the one or more embodiments of the present disclosure, and are not considered limiting of the scope of the present disclosure.

In the Figures, some elements may be shown not to scale with other elements so as to more clearly show the details. Additionally, like reference numbers are used, where possible, to indicate like elements throughout the several Figures.

It is contemplated that elements and features of one embodiment may be beneficially incorporated in the other embodiments without further recitation or illustration. For example, as the Figures may show alternative views and time periods, various elements shown in a first Figure may be omitted from the illustration shown in a second Figure without disclaiming the inclusion of those elements in the embodiments illustrated or discussed in relation to the second Figure.

FIGS. 1A and 1B provide cross-sectional views of an example VCSEL, without integrated photodiodes and with integrated photodiodes, respectively, according to embodiments of the current disclosure.

FIG. 2 provides a cross-sectional view of an example photodiode diffused into a substrate, according to embodiments of the present disclosure.

FIG. 3 is a block diagram illustrating an example system for controlling an optical power output of a VCSEL, according to embodiments of the present disclosure.

FIG. 4A is a flowchart describing an example method for controlling an optical power output of a VCSEL using a single photodiode, according to embodiments of the present disclosure.

FIG. 4B is a flowchart describing an example method for controlling an optical power output of a VCSEL using two photodiodes, according to embodiments of the present disclosure.

FIG. 5 illustrates a perspective view of an example imaging device for use with indicia decoding operations in accordance with the teachings of this disclosure.

### DETAILED DESCRIPTION

The present disclosure is generally related to an improved imaging device for use with indicia decoding operations that includes a vertical cavity surface emitting laser (VCSEL) with an integrated photodiode. The device described herein allows for the measurement of an optical power output of light emitted by the VCSEL in a much smaller footprint than conventional designs, and removes the need for splitting a laser beam for measurement purposes, among other benefits.

The described device includes a VCSEL with an n-type semiconductor substrate, a lower distributed Bragg reflector (DBR), an upper DBR, a bottom electrode contact, at least one top VCSEL cathode contact, at least one top photodiode electrode contact, a quantum well, an oxide aperture, a dielectric cap, and at least one photodiode. The VCSEL is configured to emit light away from the substrate, but a small quantity of leakage light, proportional in intensity to the optical power output of the device, travels through the lower DBR and reaches the substrate. The photodiode is positioned within the substrate in such a way that it is able to measure this small quantity of leakage light, and the measured quantity can then be used as an input for a power control loop that regulates the intensity of the VCSEL's beam.

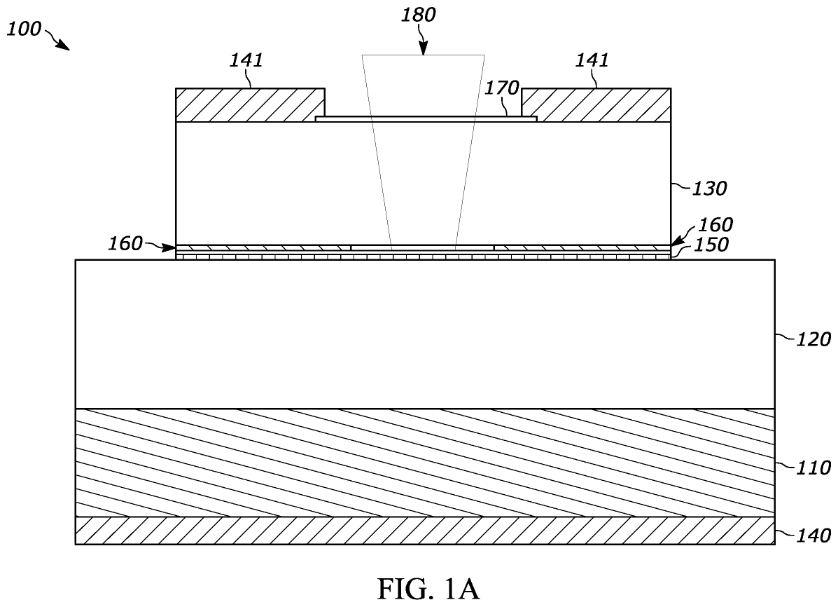

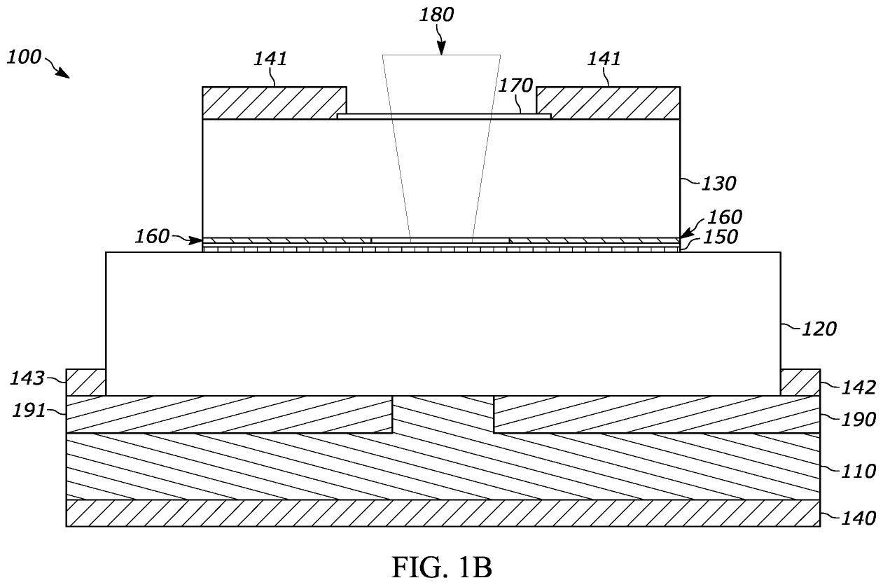

FIGS. 1A and 1B provide cross-sectional views of an example VCSEL 100, without integrated photodiodes and with integrated photodiodes, respectively, according to embodiments of the current disclosure.

In FIG. 1A, a semiconductor substrate 110 made of an n-type semiconductor material is coupled to a bottom metal electrode 140 and a lower distributed Bragg reflector (DBR) 120 made of an n-type semiconductor material opposite to the bottom metal electrode 140. The lower DBR 120 is coupled to a quantum well 150 opposite to the substrate 110, and the quantum well 150 is coupled to an upper DBR 130 made of a p-type semiconductor material opposite to the lower DBR 120. In between a portion of the quantum well 150 and the upper DBR 130 is an oxide aperture 160. A dielectric cap 170 and a metal cathode 141 are coupled to the upper DBR 130 opposite the quantum well 150, with the dielectric cap 170 located centrally and the cathode 141 disposed circumferentially around the dielectric cap 170. Responsive to the application of an electric potential across the bottom electrode 140 and the cathode 141, electric current flows through the quantum well 150. The electric current causes light to be emitted by the quantum well 150 and focused into a beam 180 by the upper DBR 130 and the lower DBR 120. The beam 180 exits the VCSEL 100 through the upper DBR 120 and the dielectric cap 170.

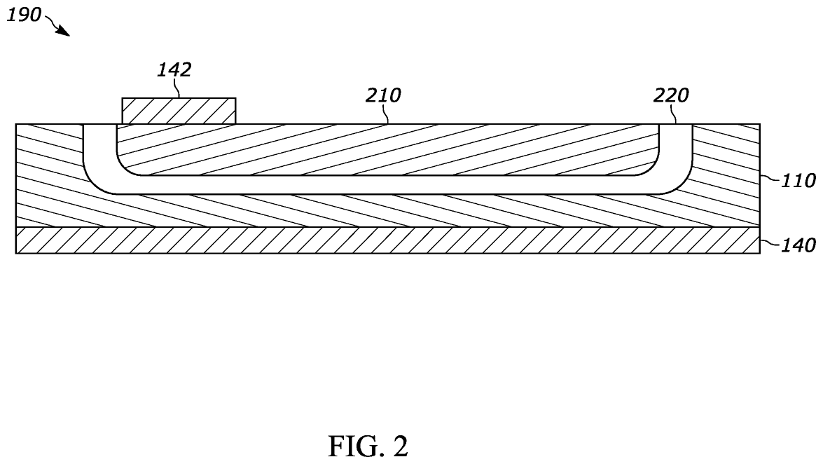

In FIG. 1B, the example VCSEL 100 shown in FIG. 1A has been modified by the addition of a photodiode 190, a redundant photodiode 191, a photodiode metal electrode 142, and a redundant photodiode metal electrode 143. The photodiode 190 and the redundant photodiode 191 are composed of p-type semiconductor material diffused into the substrate 110 (see FIG. 2) and are positioned to receive leakage light from the lower DBR 120. When the VCSEL 100 is in operation, an electric potential across the bottom electrode 140 and the photodiode electrode 142 causes an output electric current of the photodiode 190 to flow through the substrate 110 and the photodiode 190 that varies responsive to the intensity of light reaching the photodiode 190, and similarly an electric potential across the bottom electrode 140 and the redundant photodiode electrode 143 causes a redundant output electric current of the redundant photodiode 191 to flow through the substrate 110 and the redundant photodiode 191. A small quantity of light relative to the beam 180 leaks through the lower DBR 120 and strikes the photodiode 190 and the redundant photodiode 191, which causes a corresponding change in the output electric current through the photodiode 190 and the redundant output electric current through the redundant photodiode 191. The intensity of the beam 180 can be calculated by measuring the output electric current through the photodiode 190 or the redundant output electric current through the redundant photodiode 191.

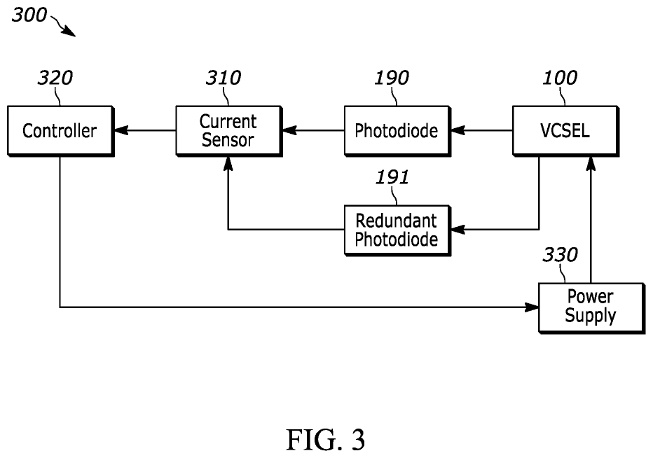

In some embodiments the redundant photodiode 191 and the redundant photodiode electrode 143 are omitted. In some embodiments the photodiode 190 is located within the substrate 110 along an axis orthogonal to a boundary plane between the lower DBR 120 and the substrate 110 on which the VCSEL 100 is configured to emit light. In some embodiments the photodiode 190 is located at least partially within a portion of the substrate 110 that is directly coupled to the lower DBR 120. In some embodiments a layer of material is integrated into or coupled to the substrate 110 at least partially between the photodiode 190 and the lower DBR 120. In some embodiments a layer of material is integrated into or coupled to the substrate 110 at least partially adjacent to the photodiode 190 on a side opposite to the lower DBR 120. In some embodiments the electric potential between the bottom electrode 140 and the photodiode electrode 142 is applied by the photodiode 190 via the photovoltaic effect. In some embodiments the photodiode 190 is a component of a feedback control system (see FIG. 3) to regulate a constant optical power of the VCSEL 100. In some embodiments, an optical power of the leakage light is less than 50% of a total optical power of the VCSEL 100. In some embodiments multiple VCSELs 100 are coupled to a single substrate 110 with at least one photodiode 190 integrated into the substrate 110 for each VCSEL 100.

FIG. 2 provides a cross-sectional view of a photodiode 190 diffused into a substrate, according to embodiments of the present disclosure. The p-type material 210 is diffused into the substrate 110, forming a depletion region 220 at a p-n junction between the p-type material 210 and the substrate 110. The substrate 110 is coupled to the bottom electrode 140, and the p-type material 210 is coupled to the photodiode electrode 142. An electric potential across the bottom electrode 140 and the photodiode electrode 142 causes the depletion layer 220 to grow, reducing capacitance between the p-type material 210 and the substrate 110. Photons colliding with the depletion region 220 create electron-hole pairs that are pulled from the depletion region 220 by an electric field that is induced by the electric potential, generating a variable current responsive to changes in a quantity of photons colliding with the depletion region 220. In some embodiments, the electric potential is applied by the photodiode 190. In these embodiments, the depletion region 220 does not grow, and instead the photovoltaic effect causes a buildup of electric potential across the bottom electrode 140 and the photodiode electrode 142 that can be used to induce an electrical current in a sensing circuit.

In some embodiments, a manufacturing process of the VCSEL 100 involves diffusing the p-type material 210 into the substrate 100 to create the p-n junctions of the photodiode 190 and the redundant photodiode 191. The diffusing of the p-type material 210 may occur before the deposition of the DBR layers of the VCSEL 100. The p-type material 210 may be created by introducing any of the following acceptor impurities or combinations thereof into the n-type substrate 110, including but not limited to Boron, Aluminum, Gallium, Indium, Germanium, Silicon, or Xenon.

FIG. 3 is a block diagram illustrating a system 300 for controlling an optical power output of a VCSEL 100, according to embodiments of the present disclosure. Leakage light from the VCSEL 100 strikes the photodiode 190 and the redundant photodiode 191 (see FIG. 1B). The first current through the photodiode 190 and second current through the redundant photodiode 191 are monitored by an electrical current sensor 310, which outputs data to be read by the controller 320. The controller 320 uses the data to calculate an optical power output of the VCSEL 100. In some embodiments the controller 320 calculates an input electrical current of the VCSEL. The controller 320 determines what action is needed to return the optical power output or current input of the VCSEL 100 to a predetermined set level (or range) and causes a power supply 330 to perform the appropriate action. In some embodiments the controller 320 communicates with the power supply 330 via a digital to analog converter. In some embodiments the current sensor 310 communicates with the controller 320 via an analog to digital converter.

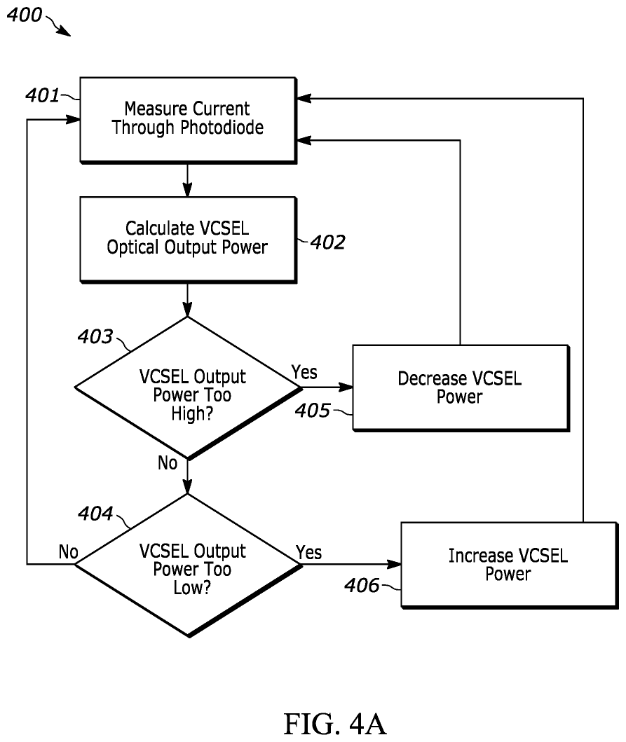

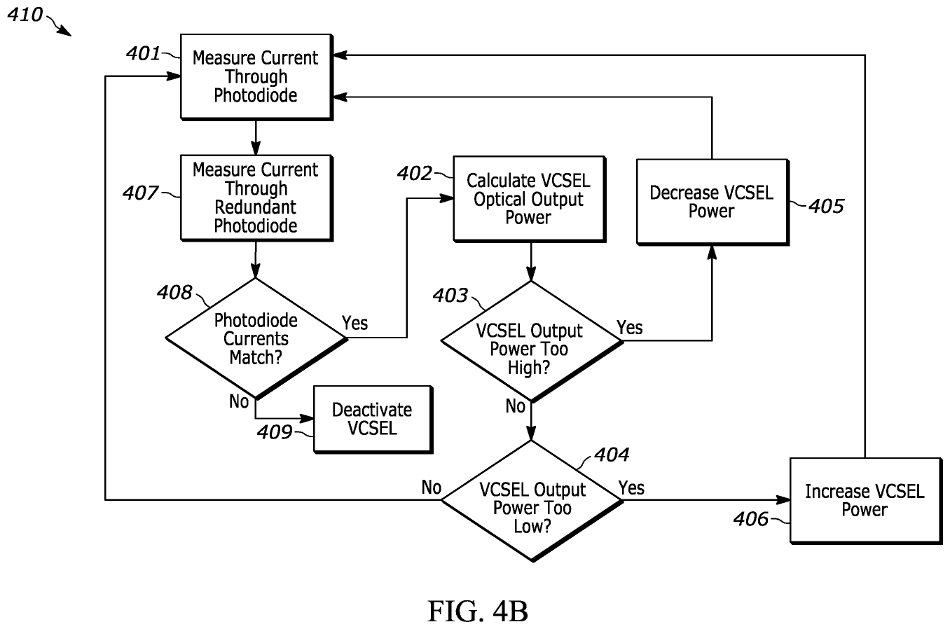

FIG. 4A is a flowchart describing a method 400 for controlling an optical power output of a VCSEL using a single photodiode, according to embodiments of the present disclosure.

At block 401, an electrical current sensor measures a current level flowing through a photodiode that varies in time proportionally to an optical power output level of a VCSEL. Data from the electrical current sensor is monitored by a controller.

At block 402, the controller calculates an optical power output value of the VCSEL using the electrical current measurement from block 401. In various embodiments, the controller calculates an electrical current input value of the VCSEL. In some embodiments, the electrical current measurement from block 401 may be replaced or combined in the calculation with other measurements, projected values, or scaling factors.

At block 403, the controller determines whether the optical power output of the VCSEL is higher than a predetermined set level (or range) based upon the optical power output value calculated at block 402. In other embodiments, the controller determines whether the electrical current input of the VCSEL is higher than the predetermined set level (or range) based upon the electrical current input value calculated at block 402. When the calculated value is too high, the method 400 proceeds to block 405 to lower the optical output power level or electrical current input level of the VCSEL. When the calculated value is not too high, the method 400 proceeds to block 404 to determine if the calculated value is lower than the set level (or range).

At block 404, the controller determines whether the optical power output of the VCSEL is lower than the set level (or range) based upon the optical power output value calculated at block 402. In other embodiments, the controller determines whether the electrical current input of the VCSEL is lower than the set level (or range) based on the electrical current input value calculated at block 402. When the calculated value is too low, the method 400 proceeds to block 406 to raise the optical output power level or electrical current input level of the VCSEL. When the calculated value is equal to the set level (or range), the method 400 returns to block 401 to measure again.

At block 405, the controller causes a power supply to decrease a quantity of electrical power being sent to the VCSEL. In various embodiments, the controller sends instructions to the power supply to decrease a supplied current or voltage. For example, the controller may communicate by sending an analog signal, a serial digital signal, a parallel digital signal via an electrical bus, or other communication means.

At block 406, the controller causes the power supply to increase a quantity of electrical power being sent to the VCSEL. In various embodiments, the controller sends instructions to the power supply to increase a supplied current or voltage. For example, the controller may communicate by sending an analog signal, a serial digital signal, a parallel digital signal via an electrical bus, or other communication means.

FIG. 4B is a flowchart describing a method 410 for controlling an optical power output of a VCSEL using two photodiodes, according to embodiments of the present disclosure. Blocks 401-406 are identical to the corresponding blocks in FIG. 4A.

At block 407, an electrical current sensor measures a verification current level flowing through a redundant photodiode that varies in time proportionally to an optical power output level of the VCSEL. Data from the electrical current sensor is monitored by the controller. In various embodiments, the controller averages the current level measured in block 401 and the verification current level measured in block 407 and uses the average value in the calculation at block 402. In such embodiments, the method 400 may proceed to block 408 to determine if a fault has developed or may omit blocks 408 and 409 and proceed directly to block 402.

At block 408 the controller compares the current level measured in block 401 to the verification current level measured in block 407. When the current level and the verification current level are equal or within a predetermined range of one another, the method 410 proceeds to block 402 to calculate an optical output power of the VCSEL. When the current level and the verification current level are not equal or are different enough from one another that they fall outside of the predetermined range, the method 410 proceeds to block 409 to deactivate the VCSEL.

At block 409, the controller has detected a fault and causes the power supply to stop sending electrical power to the VCSEL. In various embodiments, the controller may take other actions responsive to a fault condition, such as operating with a single photodiode.

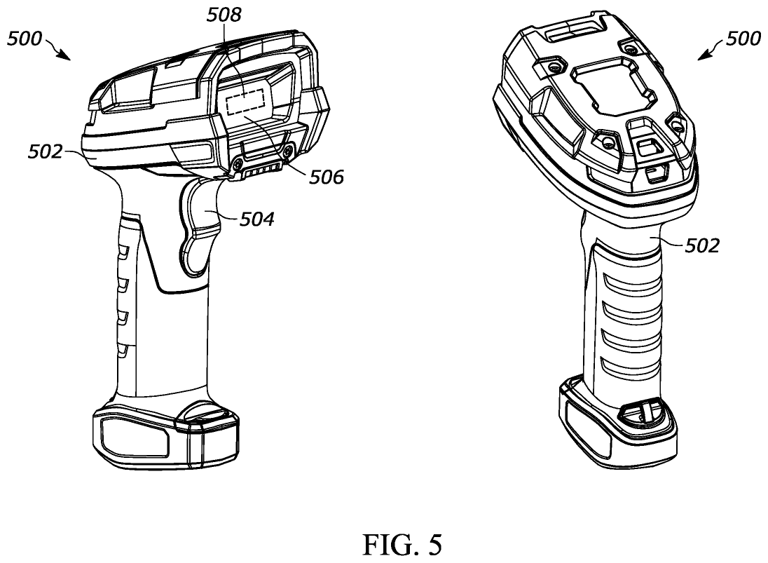

FIG. 5 illustrates a perspective view of an example imaging device for use with indicia decoding operations 500 in accordance with the teachings of the present disclosure. A housing 502 surrounds a cavity 506, and an example image sensor and aiming assembly 508 is positioned within the cavity 506. In this example, the image sensor and aiming assembly 508 is configured to capture image data through a housing window 506 and includes the VCSEL 100 that is described in further detail above.

The imaging device for use with indicia decoding operations 500 can be used in a hands-free mode as a stationary workstation when it is placed on the countertop in a supporting cradle (not shown). The imaging device for use with indicia decoding operations 500 can also be used in a handheld mode when it is picked up off the countertop (or any other surface) and held in an operator's band. In the hands-free mode, products can be slid, swiped past, or presented to the window 506. In the handheld mode, the imaging device for use with indicia decoding operations 500 can be aimed at an indicium on a product, and a trigger 504 can be manually depressed to initiate imaging of the indicium. In some implementations, the supporting cradle can be omitted, and the housing 502 can also be in other handheld or non-handheld shapes.

The descriptions and illustrations of one or more embodiments provided in this disclosure are intended to provide a thorough and complete disclosure the full scope of the subject matter to those of ordinary skill in the relevant art and are not intended to limit or restrict the scope of the subject matter as claimed in any way. The aspects, examples, and details provided in this disclosure are considered sufficient to convey possession and enable those of ordinary skill in the relevant art to practice the best mode of the claimed subject matter. Descriptions of structures, resources, operations, and acts considered well-known to those of ordinary skill in the relevant art may be brief or omitted to avoid obscuring lesser known or unique aspects of the subject matter of this disclosure. The claimed subject matter should not be construed as being limited to any embodiment, aspect, example, or detail provided in this disclosure unless expressly stated herein. Regardless of whether shown or described collectively or separately, the various features (both structural and methodological) are intended to be selectively included or omitted to produce an embodiment with a particular set of features. Further, any or all of the functions and acts shown or described may be performed in any order or concurrently.

Having been provided with the description and illustration of the present disclosure, one of ordinary skill in the relevant art may envision variations, modifications, and alternate embodiments falling within the spirit of the broader aspects of the general inventive concept provided in this disclosure that do not depart from the broader scope of the present disclosure.

As used in the present disclosure, a phrase referring to “at least one of” a list of items refers to any set of those items, including sets with a single member, and every potential combination thereof. For example, when referencing “at least one of A, B, or C” or “at least one of A, B, or C”, the phrase is intended to cover the sets of: A, B, C, A-B, B-C, and A-B-C, where the sets may include one or multiple instances of a given member (e.g., A-A, A-A-A, A-A-B, A-A-B-B-C-C-C, etc.) and any ordering thereof.

As used in the present disclosure, the term “determining” encompasses a variety of actions that may include calculating, computing, processing, deriving, investigating, looking up (e.g., via a table, database, or other data structure), ascertaining, receiving (e.g., receiving information), accessing (e.g., accessing data in a memory), retrieving, resolving, selecting, choosing, establishing, and the like.

As used in the present disclosure, the terms “substantially”, “approximately”, “about”, and other relative terms encompass values within +5% of a stated quantity, percentage, or range unless a different approximation is explicitly recited in relation to the state quantity, percentage, or range or if the context of the value indicates that a different approximation would be more appropriate. For example, a value identified as about X % may be understood to include values between 0.95*X % and 1.05*X % or between X−0.05 X and X+0.05 X percent, but may stop at zero or one hundred percent in various contexts. In another example, a feature described as being substantially parallel or perpendicular to another feature shall be understood to be within +9 degrees of parallel or perpendicular. Any value stated in relative terms shall be understood to include the stated value and any range or subrange between the indicated or implicit extremes.

As used in the present disclosure, all numbers given in the examples (whether indicated as approximate or otherwise) inherently include values within the range of precision and rounding error for that number. For example, the number 4.5 shall be understood to include values from 4.45 to 4.54, while the number 4.50 shall be understood to include values from 4.495 to 4.504. Additionally, any number or range that explicitly or by context refers to an integer amount (e.g., approximately X users, between about Y and Z states), shall be understood to round downward or upward to the next integer value (e.g., X±1 users, Y−1 and Z+1 states).

The following claims are not intended to be limited to the embodiments shown herein, but are to be accorded the full scope consistent with the language of the claims. Within the claims, reference to an element in the singular is not intended to mean “one and only one” unless specifically stated as such, but rather as “one or more” or “at least one”. Unless specifically stated otherwise, the term “some” refers to one or more. No claim element is to be construed under the provision of 35 U.S.C. § 112(f) unless the element is expressly recited using the phrase “means for” or “step for”. All structural and functional equivalents to the elements of the various aspects described in the present disclosure that are known or come later to be known to those of ordinary skill in the relevant art are expressly incorporated herein by reference and are intended to be encompassed by the claims. Moreover, nothing disclosed in the present disclosure is intended to be dedicated to the public regardless of whether such disclosure is explicitly recited in the claims.

We claim:

1. An imaging device for use with indicia decoding operations comprising an image sensor and an aiming assembly, where the aiming assembly includes:
a semiconductor substrate;
a vertical cavity surface emitting laser (VCSEL) which includes an upper distributed Bragg reflector (DBR) and a lower DBR which is coupled directly to the substrate, wherein the VCSEL is configured to emit light away from the substrate; and
a photodiode integrated into the semiconductor substrate and positioned to receive a leakage light from the DBR that is emitted towards the substrate.

2. The device of claim 1, wherein the photodiode is located at least partially in a portion of the substrate that is coupled to the DBR.

3. The device of claim 2, wherein a layer of material is integrated into or coupled to the substrate at least partially between the DBR and the photodiode.

4. The device of claim 2, wherein a layer of material is integrated into or coupled to the substrate at least partially adjacent to the photodiode opposite the DBR.

5. The device of claim 1, wherein a second photodiode is integrated into the semiconductor substrate and is positioned to accept a second leakage light from the DBR.

6. The device of claim 1, wherein the photodiode is integrated at least partially into a portion of the semiconductor substrate that is along an axis on which the VCSEL is configured to emit light.

7. The device of claim 1, wherein the photodiode is used in a feedback control system to regulate a constant optical power of the VCSEL.

8. The device of claim 7, wherein the control system includes a constant optical power control loop.

9. The device of claim 8, wherein the photodiode detects a level of emitted light, and responsive to the level of emitted light being outside of a predetermined range the constant optical power control loop increases or decreases a current input level of the VCSEL.

10. The device of claim 7, wherein the control system includes a constant current control loop.

11. The device of claim 10, wherein the photodiode detects a level of emitted light, and responsive to the level of emitted light being outside of a predetermined range the constant current control loop increases or decreases a current input level of the VCSEL.

12. The device of claim 1, wherein the leakage light comprises less than 50% of a total quantity of light emitted by the VCSEL.

13. A method for measuring power output from a vertical cavity surface emitting laser (VCSEL) comprising:
detecting an amount of optical power of a leakage light emitted towards a semiconductor substrate by a distributed Bragg reflector (DBR) coupled directly to the substrate in a VCSEL configured to emit light away from the substrate;
calculating an output level of the VCSEL based upon the amount of optical power of the leakage light; and
adjusting the output level of the VCSEL responsive to the output level being greater or lesser than a target output level or range.

14. The method of claim 13, wherein detecting comprises measuring a first current level passing through a first photodiode that is integrated into the VCSEL.

15. The method of claim 13, wherein adjusting the output level includes using a constant current control loop.

16. The method of claim 13, wherein adjusting the output level includes using a constant optical power control loop.

17. The method of claim 13, wherein detecting comprises measuring a current level passing through a first photodiode and a redundant second photodiode is configured as a cross check device.

18. The method of claim 13, wherein detecting comprises measuring a current level passing through a first photodiode and a redundant second photodiode is configured as a back-up device.

19. A method for manufacturing a vertical cavity surface emitting laser (VCSEL) comprising diffusing a P-N junction into a semiconductor substrate coupled directly to one of two distributed Bragg reflectors.
